(19) United States
(12) Patent Application Publication
(10) Pub. No.: US 2015/0194582 A1
(43) Pub. Date: Jul. 9, 2015

(54) LIGHT REFLECTING SUBSTRATE FOR LED APPLICATIONS

(71) Applicant: CeramTec GmbH, Plochingen (DE)

(72) Inventors: Alexander Dohn, Memmelsdorf (DE); Alfred Thimm, Wunsiedel (DE)

(73) Assignee: CeramTec GmbH, Plochingen (DE)

(21) Appl. No.: 14/410,858

(22) PCT Filed: Jul. 8, 2013
(86) PCT No.: PCT/EP2013/064378

§ 371 Date: Jan. 7, 2015

(30) Foreign Application Priority Data
Jul. 9, 2012 (DE) 10 2012 211 899.3

(51) Int. Cl. H01L 33/60; C23C 18/54; H01L 33/00; C23C 14/34; H01L 33/62; H01L 33/46

(52) U.S. Cl. CPC H01L 33/60; H01L 33/62; H01L 33/46; H01L 33/0095; C23C 14/34; C23C 18/54

(57) ABSTRACT

A ceramic substrate (1) with an upper side (4) and an under side (5) opposite to said upper side (4), wherein a metallization (2) is applied to the upper side (4), said metallization being connected in an electrically conducting manner to the electrical connecting elements of at least one LED (3). In order to permanently increase the reflection, according to the invention a layer (6) reflecting light towards the LED (3) or the LEDs (3) is arranged on the underside (5).

The invention relates to a ceramic substrate having an upper side and a lower side located opposite the upper side, wherein a metallization, which is connected in an electrically conducting manner to electrical connecting elements of at least one LED, is applied to the upper side.

Substrates made of aluminum oxide typically have a reflectance in the range of visible light of approximately 85 to 90%. For LED applications, it is desirable to further increase this reflectance. Even small increases are advantageous for this purpose. For this reason, it is known to apply a light-reflecting layer to the upper side of the substrate between the LED and the substrate, with the exception of the metallization. The disadvantage here is that this layer is not protected from atmospheric influences, and consequently the light-reflecting effect thereof diminishes even after a short time, and completely disappears over the long term.

It is therefore the object of the invention to improve a ceramic substrate according to the preamble of claim 1 in such a way that the reflectance is increased over the long term, and if possible, during the entire service life.

According to the invention, this object is achieved by the features of claim 1.

Due to a layer which reflects light toward the LED, or toward the LEDs, being disposed on the lower side, the light-reflecting layer is protected from atmospheric influences, or can additionally be easily protected from atmospheric influences, and thus permanently retains the light-reflecting effect thereof and reflectance is permanently increased.

In one embodiment, the light-reflecting layer is made of a reflective metal, such as silver.

In an alternative embodiment, the light-reflecting layer is made of a bright white, light-reflecting non-metallic material, such as magnesium oxide or titanium dioxide.

The substrate is preferably made of aluminum nitride or aluminum oxide or another white ceramic material.

In one embodiment according to the invention, the substrate is made of aluminum nitride, and the light-reflecting layer is an oxide layer. Such oxide layers are white and have high reflectance. Thermal conductivity drops only by approximately 5% in the conversion.

An oxide layer having a thickness of 5 to 10 μm is advantageous because it has good adhesive power and sufficient reflectance.

To avoid diffuse reflection, it is additionally proposed that the substrate is polished on the upper side. Polishing of the lower side can support the targeted reflection at an angle of 90° relative to the lower side.

To dissipate the heat generated by the LED, it is preferred if the metallization is sintered on the substrate.

A method according to the invention for producing a ceramic substrate, as described above, is characterized in that the light-reflecting layer is applied to the lower side by way of sputtering, screen printing or a galvanic process (electroplating), or the light-reflecting layer is applied as an oxide layer by way of conversion of the substrate in an oxygen-containing atmosphere at a temperature of >500 degrees C. During this conversion, a reaction from AlN to Al2O3 occurs. This conversion is carried out prior to the metallization. An oxide layer is also understood to mean an oxide crust.

Preferably, the sputtering is carried out using a silver target, the screen printing is carried out using a paste that is baked at 600 to 900° C. in air after application, and the galvanic process is an electroless deposition of silver.

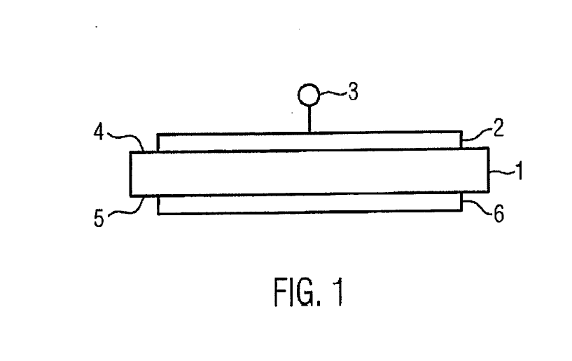

FIG. 1 shows a substrate 1 made of aluminum oxide having a metallization 2 which is applied to the upper side 4 of the substrate and to which the connecting elements of an LED 3, or of multiple LEDs, are connected in an electrically conducting manner. The metallization 2 is preferably sintered with the substrate 1 and forms printed conductors for an electric circuit, or at least contacting points for the LED 3 or the LEDs 3.

A layer 6 reflecting light toward the LED 3, or toward the LEDs 3, is applied to the lower side 5 of the substrate 1.

1.-10. (canceled)

11. A ceramic substrate comprising:
an upper side;
a lower side disposed opposite the upper side;
a metallization which is connected in an electrically conducting manner to electric connecting elements of at least one LED being applied to the upper side; and
a layer reflecting light toward the LED disposed on the lower side.

12. The ceramic substrate according to claim 11, wherein the light-reflecting layer comprises a reflective metal.

13. The ceramic substrate according to claim 12, wherein the reflective metal is silver.

14. The ceramic substrate according to claim 11, wherein the light-reflecting layer comprises a bright white, light-reflecting non-metallic material.

15. The ceramic substrate according to claim 14, wherein the bright white, light-reflecting non-metallic material is selected from the group consisting of magnesium oxide and titanium dioxide.

16. A ceramic substrate according to claim 11, wherein the substrate comprises a white ceramic material.

17. A ceramic substrate according to claim 11, wherein the substrate comprises a ceramic selected from the group consisting of aluminum nitride and aluminum oxide.

18. The ceramic substrate according to claim 11, wherein the substrate comprises aluminum nitride and the light-reflecting layer comprises an oxide.

19. The ceramic substrate according to claim 18, wherein the light-reflecting layer (6).

20. The ceramic substrate according to claim 18, wherein the oxide layer has a thickness of 5 to 10 μm.

21. A ceramic substrate according to claim 11, wherein the upper side of the substrate is polished.

22. A ceramic substrate according to claim 11, wherein the metallization is sintered on the substrate.

23. A method for producing a ceramic substrate according to claim 11, comprising the steps of:
applying the light-reflecting layer to the lower side by sputtering, screen printing, a galvanic process, or as an oxide layer by way of conversion of the substrate in an oxygen-containing atmosphere at a temperature of >500° C.

24. The method according to claim 23, wherein the sputtering is carried out using a silver target, the screen printing is carried out using a paste that is baked at 600 to 900° C. in air after application, and the galvanic process is an electroless deposition of silver.

25. A ceramic substrate according to claim 12, wherein the upper side of the substrate is polished.

26. A ceramic substrate according to claim 12, wherein the metallization is sintered on the substrate.

27. A ceramic substrate according to claim 13, wherein the upper side of the substrate is polished.

28. A ceramic substrate according to claim 13, wherein the metallization is sintered on the substrate.

29. A ceramic substrate according to claim 14, wherein the upper side of the substrate is polished.

30. A ceramic substrate according to claim 14, wherein the metallization is sintered on the substrate.
